(19) United States
(12) Patent Application Publication
(10) Pub. No.: US 2006/0286771 A1
(43) Pub. Date: Dec. 21, 2006

(54) Layer transfer technique

(76) Inventors: Mohamad Shaheen, Portland, OR (US); Ruitao Zhang, Portland, OR (US); Ryan Lei, Hillsboro, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/509,147

(22) Filed: Aug. 23, 2006

Related U.S. Application Data
(62) Division of application No. 10/608,406, filed on Jun. 26, 2003, now abandoned.

(51) Int. Cl. H01L 21/30

(52) U.S. Cl. 438/458

(57) ABSTRACT

A layer transfer technique in which a portion of a donor wafer is doped with positively charged hydrogen ions and positively charged helium ions before it is bonded to a portion of a handle wafer. Furthermore, the bonded wafers are annealed at one of two annealing temperatures, which determines whether the wafers are separated using a thermal cleave or a mechanical cleave process.

### RELATED APPLICATIONS

This application is a divisional application of U.S. application Ser. No. 10/608,406, filed Jun. 26, 2003, currently pending.

### FIELD OF THE INVENTION

Embodiments of the invention relate to semiconductor manufacturing. More particularly, embodiments of the invention relate to the transferring of a material, such as an epitaxial silicon layer, to a film, such as a silicon-dioxide film, on a silicon substrate and minimizing costs that can result from the transfer and subsequent annealing of the transferred material.

### BACKGROUND

Various techniques are used in modern semiconductor processing to create an epitaxial layer on a wafer. At least one prior art transfer technique is used to create a structure having an epitaxial layer, such as an epitaxial silicon wafer, bonded to another wafer having a semiconductor substrate. Typically, the layer to be transferred originates from a donor wafer and is bonded to a recipient wafer, typically referred to as a handler wafer, and separated from the donor wafer through a thermal or mechanical operation.

Prior art techniques for performing a layer transfer from a donor wafer to a handle wafer typically require a relatively high dosage of a single type of implanted ions in order to facilitate the transfer of a layer from the donor wafer material to the handle wafer material. The implanted ions typically diffuse and react with donor wafer material, forming bonds, around which voids may form. These voids can help create a cleave plane, along which the donor and handle wafers can be thermally or mechanically separated.

FIG. 1 illustrates a typical prior art layer transfer technique in which a donor and handle wafer are brought into contact and bonded. After the bond is complete, the wafers are separated along a cleave plane within the donor wafer, such that a layer is effectively transferred from the donor wafer to the handle wafer.

In order to further facilitate separation, a high temperature annealing process can be performed, in which the bonded donor-handle pair enters a furnace where it is exposed to a high ambient temperature to strengthen the bonds between the donor and handle material, as well as to help diffuse the implanted ions and promote the reaction of the implanted ions with the silicon.

As the annealing temperature is increased, voids can form around the implanted ions that have bonded with the layer to be transferred. The voids may eventually coalesce to create a suitable cleaving plane, along which the bonded donor and handle wafers may be separated.

In another prior art example illustrated in FIG. 2, the formation of a structure, such as a silicon-on-insulator (SOI) structure 201, on a handle wafer material, such as a silicon substrate, can use an implantation of approximately 5×10¹⁶ cm⁻² of hydrogen ions (H₂⁺) and annealing temperatures of approximately 500 degrees Centigrade (C.) or higher. Furthermore, an annealing process in which one bonded wafer pair enters an anneal furnace and two separated wafers are removed from the anneal furnace can require special or additional handlers to complete the anneal process. As a result, prior art wafer transfer techniques using relatively large quantities of dopants, high anneal temperatures, and/or special or additional handling equipment can contribute to relatively high semiconductor manufacturing costs.

### BRIEF DESCRIPTION OF THE DRAWINGS

Embodiments of the invention are illustrated by way of example and not limitation in the figures of the accompanying drawings, in which like references indicate similar elements and in which:

FIG. 1 illustrates a typical prior art layer transfer technique.

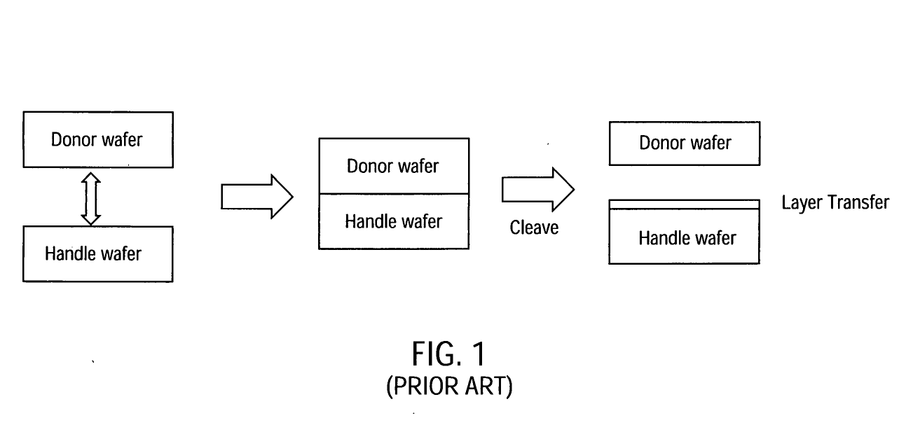

FIG. 2 illustrates a prior art layer transfer technique in which a silicon-on-insulator (SOI) structure is formed.

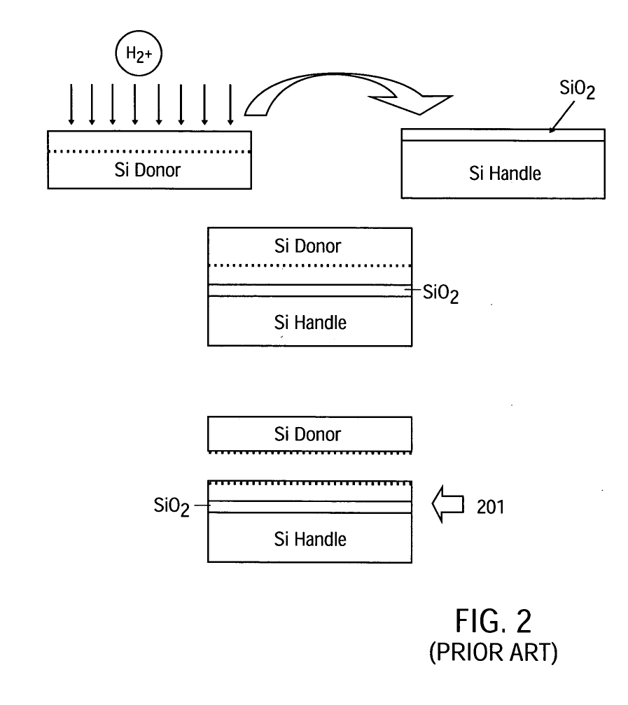

FIG. 3 illustrates a layer transfer technique according to one embodiment of the invention in which He⁺ and H⁺ ions are implanted a silicon donor layer.

FIG. 4 illustrates a layer transfer technique according to one embodiment of the invention in which He⁺ and H⁺ ions are implanted into a Ge (germanium) donor layer.

FIG. 5 illustrates a layer transfer technique according to one embodiment of the invention in which He⁺ and H⁺ ions are implanted into a compound having elements from group III and group IV of the periodic table (III-IV donor compounds), such as gallium-arsenide (GaAS), indium phosphide (InP), gallium-nitride (GaN), gallium antimonide (GaSb), or indium antimonide (InSb).

FIG. 6 illustrates the thermal cleave characteristics of an embodiment of the invention in which an approximately equal quantity of H⁺ ions and He⁺ ions are implanted into the donor wafer material.

FIG. 7 is a flow diagram illustrating a technique for transferring one wafer structure to another according to one embodiment of the invention.

### DETAILED DESCRIPTION

Embodiments of the invention pertain to a semiconductor processing technique in which a layer of one wafer is transferred to another wafer. More particularly, at least one embodiment of the invention pertains to an improved technique for forming an epitaxial layer on a handle wafer by transferring a portion of a donor wafer to the handle wafer.

The amount of implanted ions to facilitate the separation of a layer of material from a donor wafer after it has been bonded to a handle wafer can be reduced, in at least one embodiment of the invention, by implanting positively charged hydrogen (H⁺) and helium (He⁺) ions into the donor wafer material. In embodiments of the invention in which H⁺ and He⁺ are implanted into a donor wafer, the H⁺ ions help to create voids in the donor material, such as silicon, by combining with the donor material to form bonds, such as Si—H bonds.

The implanted He⁺ ions help to expand these voids in order to create a cleave plane within the donor wafer when the bonded donor and handle wafers are annealed. The cleave plane provides a structural weakness within the donor wafer, along which the donor wafer may be separated from the layer to be transferred by using a thermal or mechanical separation technique.

In other embodiments of the invention other combination of ions may be implanted to facilitate layer transfer, such as ions of noble gases, argon (Ar), neon (Ne), and xenon (Xe), in combination with ions of active species, such as nitrogen (N₂). Noble ions in combination with active species ions serve, in at least one embodiment of the invention, a similar function in the layer transfer as H⁺ and He⁺ do in other embodiments of the invention.

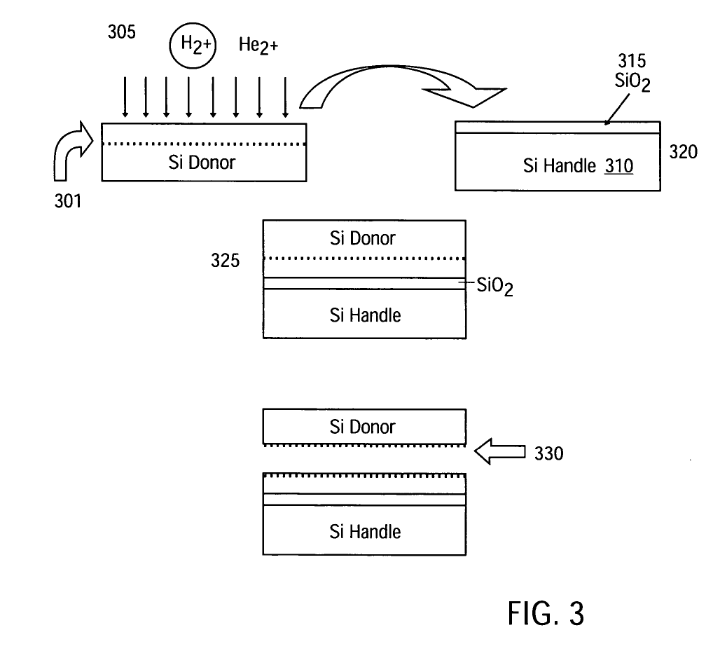

FIG. 3 illustrates the formation of a silicon-on-insulator (SOI) structure according to one embodiment of the invention. The silicon donor wafer 301 is implanted with H⁺ and He⁺ ions 305 and bonded with a handle wafer 310 having a silicon-dioxide (SiO₂) film 315 deposited on a surface of a silicon substrate 320. The transfer layer 325 from the silicon donor wafer is separated along a cleave plane 330 formed in part by the implanted ions and in part by an anneal process.

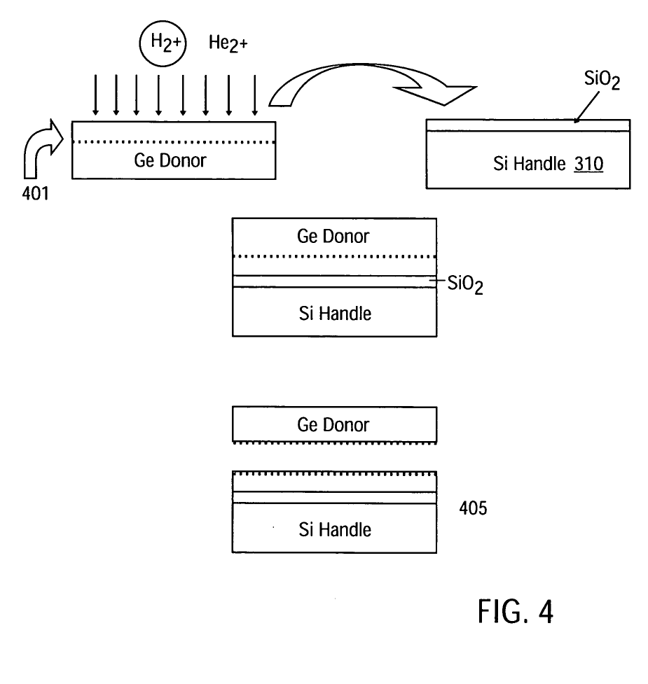

Embodiments of the invention are not limited to the type of donor or handle wafer material illustrated or discussed in FIG. 3. Indeed, other donor and handle wafer materials may be used in other embodiments of the invention. FIG. 4, for example, illustrates an embodiment of the invention in which a Ge layer is transferred from a Ge donor wafer 401 to create a structure 405 having layers of Ge, SiO₂, and Si.

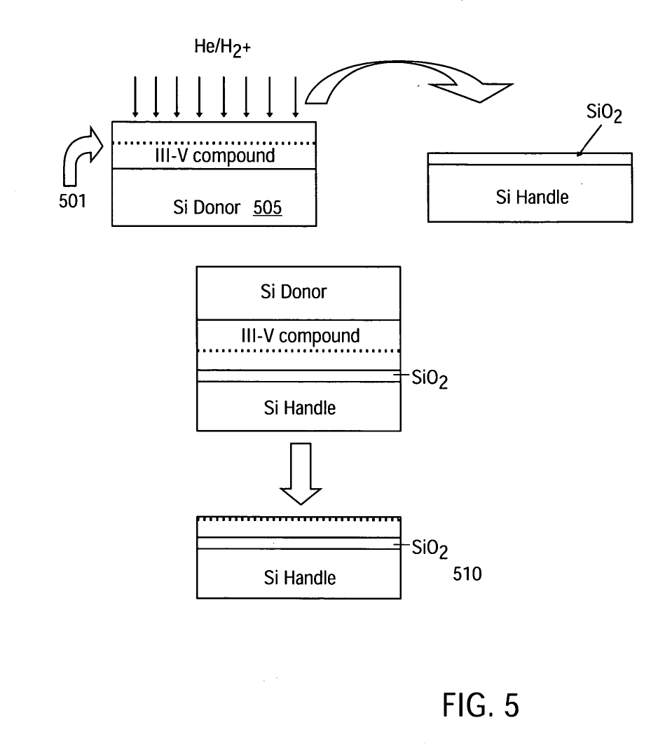

In other embodiments of the invention, other layer types may be transferred that differ from the material of the donor wafer substrate. FIG. 5, for example illustrates one embodiment of the invention in which a III-V compound 501, such as gallium-arsenide (GaAS), InP, gallium-nitride (GaN), GaSb, and InSb, is transferred from a donor wafer 505 to form a structure 510 having a III-V layer compound layer, a SiO₂ layer, and an Si substrate.

In one embodiment of the invention, approximately equal dosages of the implanted ions are used. For example, in one embodiment of the invention, 1×10 ¹⁶ cm⁻² of H⁺ ions and 1×10¹⁶ cm⁻² of He⁺ ions are implanted into the donor silicon wafer material. In other embodiments the ratio of these two dopants can be different, but, in at least one embodiment of the invention, a sum of no more than approximately 2 to 3×10¹⁶ cm⁻² of He⁺ ions and H⁺ ions is used to achieve an effective layer transfer. This sum, however, may be higher in other embodiments of the invention, depending at least in part on the donor and handle materials used, the annealing duration and temperature, and the ions to be implanted.

In one embodiment of the invention, He⁺ and H⁺ ions are chosen because they can have similar peak energy ranges and can, therefore, react with the material in which they are implanted in a uniform and consistent manner. For example, in one embodiment of the invention the H⁺ ions react with the donor wafer material to help form voids in the donor wafer material at an energy level of approximately 40 KeV, whereas the He+ ions react to help expand the voids within the donor wafer material at an energy level of approximately 50 KeV.

The separation of the donor and handle wafer is completed by a thermal or mechanical separation process, depending in part on the duration and in part on the temperature of the annealing process. One example in which one embodiment of the invention is used employs an annealing process of approximately 10 minutes in duration. Duration of the annealing process is application dependent, however, and embodiments of the invention do not depend upon nor are in anyway limited by the duration of the annealing process. Advantageously, embodiments of the invention enable relatively low annealing temperatures to be used in order to create a suitable cleave plane along which to separate the handle and donor wafers.

In one embodiment of the invention, complete layer transfer is achieved without the use of a mechanical cleaving operation if the embodiment uses an annealing temperature of at least approximately 440 degrees C. Such an embodiment of the invention, however, may require special or additional handling equipment to place a bonded wafer into the annealing furnace and to remove two separated wafers from the furnace.

Embodiments of the invention using an annealing temperature of no greater than approximately 430 degrees C., on the other hand, may not need special or additional handling equipment, because complete layer transfer may not be completed without a mechanical cleave operation after the wafer pair is removed from the annealing furnace.

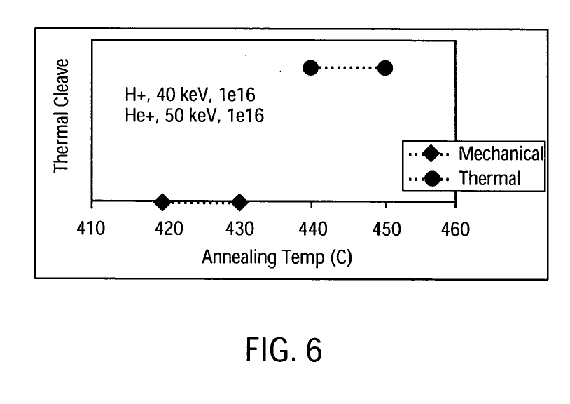

FIG. 6 illustrates thermal cleave characteristics of at least one embodiment of the invention, in which an approximately equal amount of implanted He⁺ and H⁺ ions having approximately equal reaction energy ranges are implanted in the donor wafer. The energy reaction range of an ion is the energy level at which the ion will bond with atoms of another material.

As FIG. 6 illustrates, embodiments of the invention using an annealing temperature of approximately 420 degrees C. to 430 degrees C. may use a mechanical cleave operation to achieve complete wafer separation, whereas embodiments using an annealing temperature of approximately 440 degrees C. to 450 degrees C. may use a thermal cleave operation to complete the layer transfer.

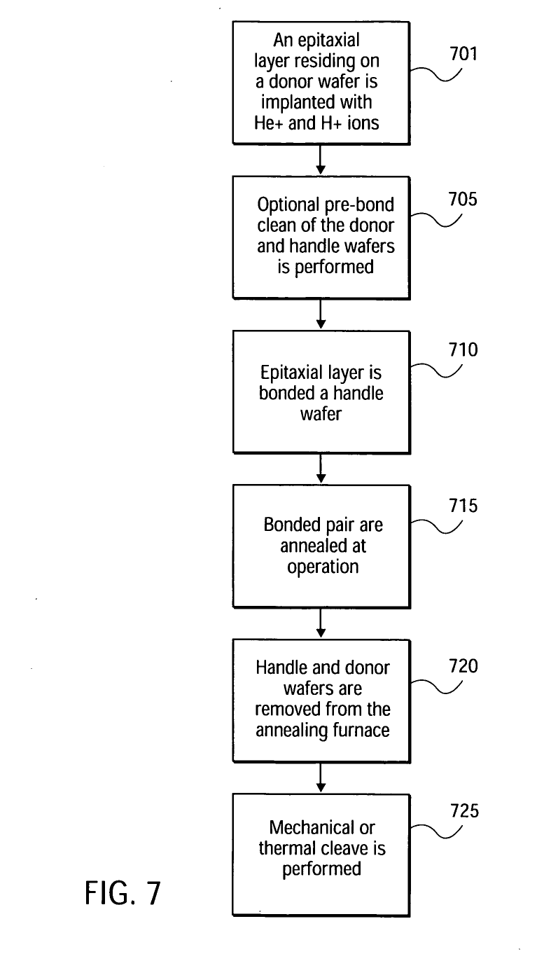

FIG. 7 is a flow diagram illustrating a number of operations used to carry out one embodiment of the invention. At operation 701, an epitaxial layer residing on a donor wafer is implanted with He⁺ and H⁺ ions. An optional pre-bond clean of the donor and handle wafers is performed at operation 705. The epitaxial layer is bonded a handle wafer at operation 710 and the pair are annealed at operation 715. The handle and donor wafers are removed from the annealing furnace at operation 720 and a mechanical cleave is performed at operation 725 to completely separate the donor/handle pair if the annealing temperature is 430 degrees C. or less. If the annealing is performed at approximately 440 degrees C. or more, the donor and handle wafers may be thermally separated.

While the invention has been described with reference to illustrative embodiments, this description is not intended to be construed in a limiting sense. Various modifications of the illustrative embodiments, as well as other embodiments, which are apparent to persons skilled in the art to which the invention pertains are deemed to lie within the spirit and scope of the invention.

1-8. (canceled)

9. A method comprising:
implanting a first wafer, including a substantially first layer, with a first quantity of helium ions and a second quantity of hydrogen ions;
introducing a surface of a second wafer, including a silicon substrate, to a surface of the first layer;
annealing the first layer and the silicon substrate at a first temperature for a first amount of time.

10. The method of claim 9 further including separating a portion of the first layer from the first wafer that is not bonded with the silicon substrate after the first amount of time.

11. The method of claim 10 wherein the sum of the first quantity of helium ions and the second quantity of hydrogen ions is no greater than approximately 2×10¹⁶ cm⁻².

12. The method of claim 11 wherein the first quantity of helium ions is no greater than approximately 1×10¹⁶ cm⁻².

13. The method of claim 11 wherein the second quantity of hydrogen ions is no greater than approximately 1×10¹⁶ cm⁻².

14. The method of claim 9 further comprising forming voids in the first layer as a result of the second quantity of hydrogen ions interacting with the substrate.

15. The method of claim 14 wherein the second quantity of hydrogen ions have an energy range of approximately 40 KeV.

16. The method of claim 15 wherein the first quantity of helium ions help the voids to expand at an energy level of approximately 50 KeV.

17. The method of claim 9 wherein the first temperature is approximately 440 C and the first amount of time is approximately 10 minutes

18. A process comprising:
forming an epitaxial layer on a donor wafer;
forming a film oxide on a handle wafer;
transferring a portion of the epitaxial layer to the handle wafer, the transferring including implanting the epitaxial layer with a first quantity of positively charged helium ions and a second quantity of positively charged hydrogen ions.

19. The process of claim 18 wherein the transferring further comprising performing an annealing process on the donor wafer and handle wafer while they are in direct contact with each other.

20. The process of claim 19 wherein the annealing temperature is no greater than approximately 430 C.

21. The process of claim 18 wherein the sum of the first quantity helium ions and the second quantity of hydrogen ions is approximately 2×10¹⁶ cm⁻².

22. The process of claim 20 wherein the transferring further comprises using a mechanical cleave process to separate a portion of the epitaxial layer from the handle wafer.

23. The process of claim 21 wherein the first quantity of helium ions is approximately 1×10¹⁶ cm⁻².

24. The process of claim 23 wherein the second quantity of hydrogen ions is approximately 1×10¹⁶ cm⁻².

25. The process of claim 18 wherein the film oxide comprises SiO₂.

26. The process of claim 25 wherein the epitaxial layer is chosen from a group consisting of silicon, Ge, GaAS, InP, GaN, GaSb, and InSb.

27-35. (canceled)
